(19) United States
(12) Patent Application Publication
(10) Pub. No.: US 2024/0088044 A1
(43) Pub. Date: Mar. 14, 2024

(54) ACCESS CIRCUITRY STRUCTURES FOR THREE-DIMENSIONAL MEMORY ARRAY

(71) Applicant: Micron Technology, Inc., Boise, ID (US)

(72) Inventors: Collin Howder, Boise, ID (US); Taehyun Kim, Boise, ID (US)

(21) Appl. No.: 17/940,715

(22) Filed: Sep. 8, 2022

(51) Int. Cl. H01L 23/535; H01L 23/528; H01L 27/11556; H01L 27/11582

(52) U.S. Cl. CPC H01L 23/535; H01L 23/5283; H01L 27/11556; H01L 27/11582

(57) ABSTRACT

Methods, systems, and devices for access circuitry structures for three-dimensional (3D) memory arrays are described. A memory device may include levels of memory cells over a substrate. To support accessing memory cells at respective levels, the memory device may include a conductive pillar extending through the levels of memory cells and coupled with one or more memory cells at respective levels of memory cells. The memory device may include a bit line and a contact that is configured to couple the bit line with the conductive pillar. The conductive pillar may be formed such that it extends into a portion of the contact, and a contact resistance between the conductive pillar and the bit line may be based on the conductive pillar extending into the portion of the contact.

### FIELD OF TECHNOLOGY

The following relates to one or more systems for memory, including access circuitry structures for three-dimensional (3D) memory arrays.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 illustrates an example of a system that supports access circuitry structures for three-dimensional (3D) memory arrays in accordance with examples as disclosed herein.

FIG. 2 illustrates an example of a memory architecture that supports access circuitry structures for 3D memory arrays in accordance with examples as disclosed herein.

FIGS. 3A, 3B, 3C, 3D, 3E, 3F, 3G, and 3H illustrates examples of operations of a manufacturing process that support access circuitry structures for 3D memory arrays in accordance with examples as disclosed herein.

FIG. 4 shows a flowchart illustrating a method or methods that support access circuitry structures for 3D memory arrays in accordance with examples as disclosed herein.

### DETAILED DESCRIPTION

Memory devices may include one or more arrays of memory cells and associated circuitry over a substrate. For example, a memory device may include three-dimensional (3D) arrays of memory cells that are arranged in respective levels (e.g., layers, decks, tiers) of memory cells. In some examples, the memory device may include access circuitry (e.g., word lines, bit lines) located at respective levels, if not each level, of memory cells to support accessing memory cells located at respective levels. In some cases, the memory device may include one or more conductive pillars (e.g., a doped hollow channel (DHC)), which may extend through one or more levels of memory cells and may be used to couple a bit line with one or more memory cells at respective levels of memory cells. To access a selected memory cell, current may pass from the bit line to the selected memory cell via the one or more conductive pillars (e.g., or from the memory cell to the bit line via the conductive pillar, for example, based on a voltage differential applied across the memory cell).

In some cases, the amount of current passed to the selected memory cell may depend on a resistance between the bit line and a conductive pillar. For example, a higher resistance between the hit line and the conductive pillar may be associated with decreased current passed to the conductive pillar and, in turn, the selected memory cell. In some cases, a quantity of levels of memory cells included in the memory device may be limited based on the current able to be passed to the conductive pillar (e.g., the less current able to be passed, the fewer levels of memory cells that may be supported). Thus, lowering the resistance between the bit line and the conductive pillar may increase the quantity of levels of memory cells that may be included in the memory device, which may increase a storage capacity of the memory device. Additionally, lowering the resistance may reduce power consumption of the memory device, for example, by supporting a reduced amount of current to be passed through bit lines.

In accordance with examples described herein, a conductive pillar used to access memory cells at various levels and a contact used to couple the conductive pillar with a bit line may be formed such that a contact area between the conductive pillar and the contact may be increased compared to other different examples, thereby decreasing a resistance between the conductive pillar and the bit line. For example, an increased surface area of the contact and the conductive pillar that are in contact may be associated with a decreased resistance. Forming the conductive pillar such that it protrudes into the contact may increase the surface area of the conductive pillar that is in contact and coupled with the contact, which will reduce the resistance between the conductive pillar and the contact, and thus between the conductive pillar and the bit line. For example, if the conductive pillar protrudes at least partially into the contact, one or more sidewalls of the conductive pillar (e.g., rather than just a top surface of the conductive pillar) may be in contact with one or more conductive materials of the contact, thereby increasing the surface area of the conductive pillar that is coupled with the contact. Thus, the resistance between the conductive pillar and the bit line will be reduced, thereby supporting scaling of the memory device (e.g., an increased quantity of levels of memory cells) and increasing a storage capacity of the memory device.

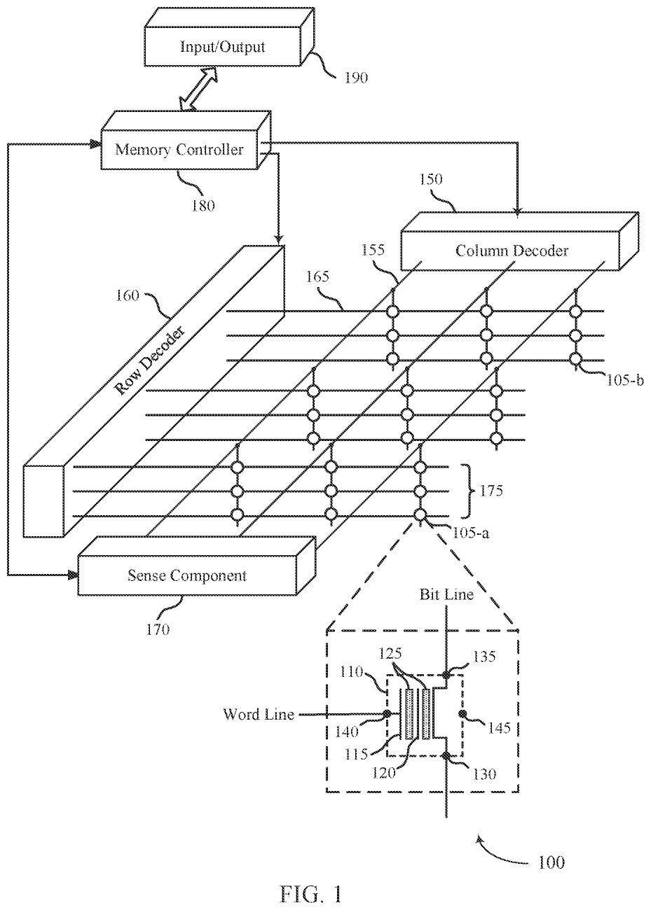

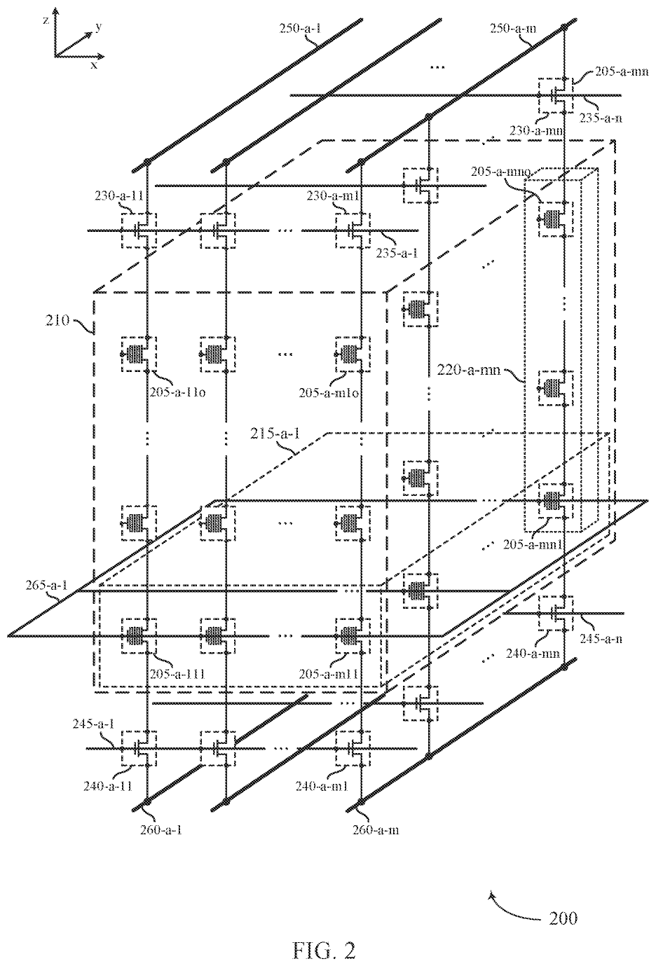

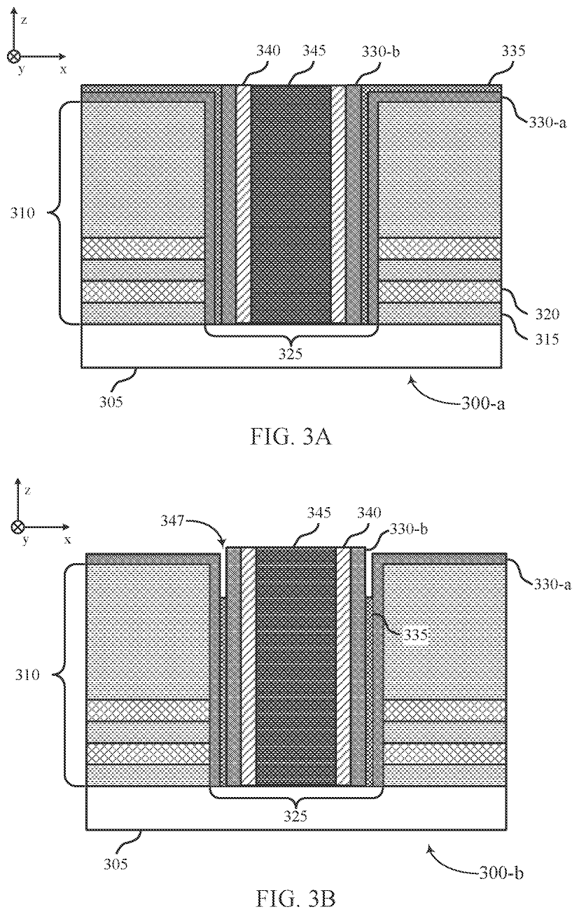

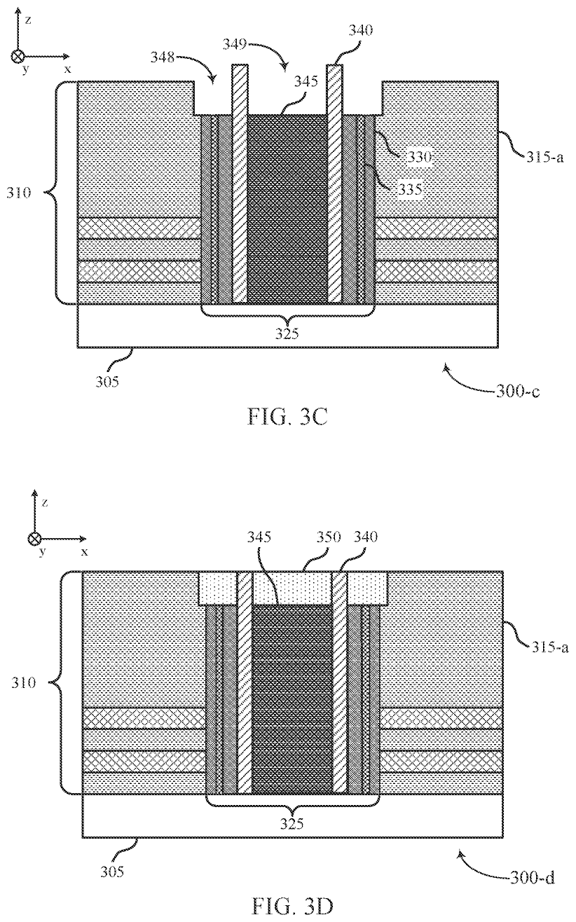

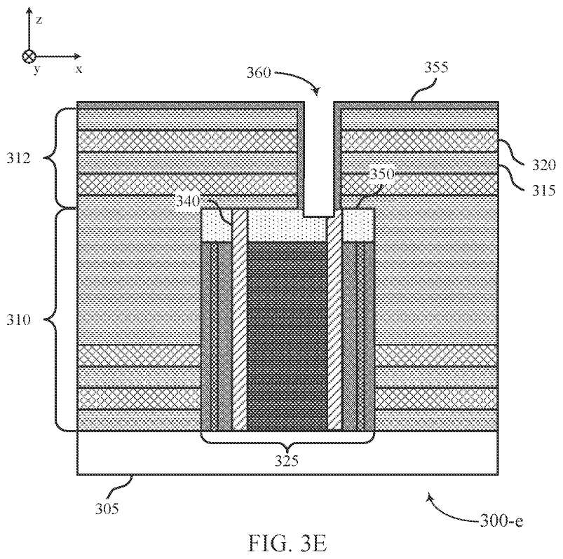

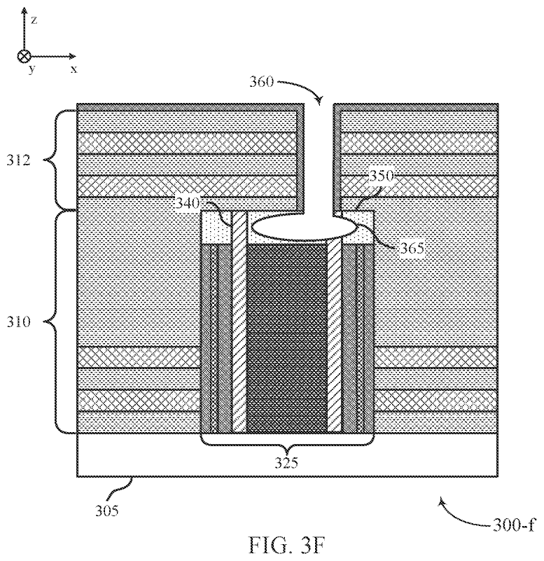

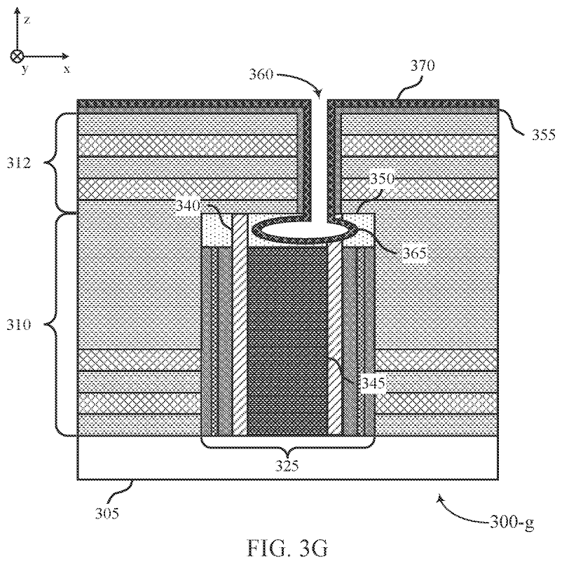

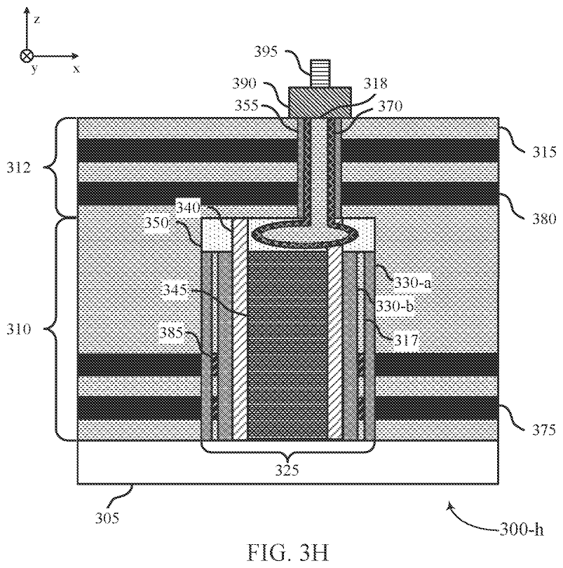

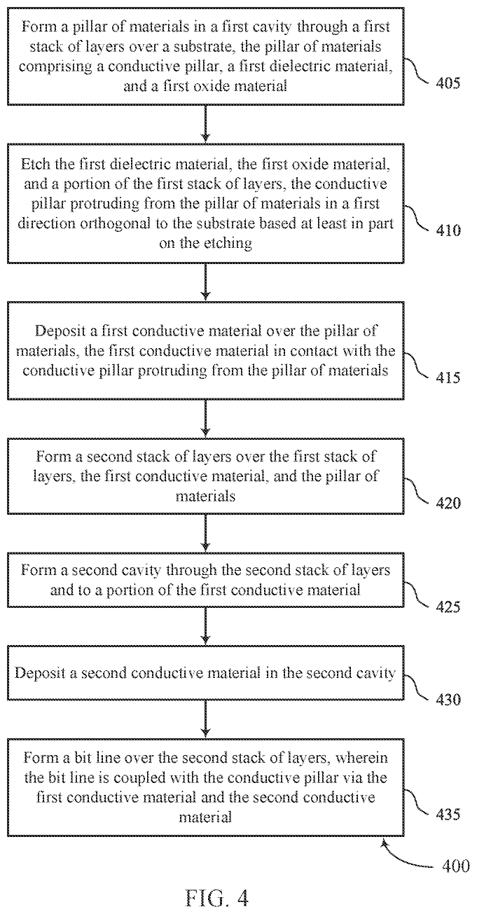

Features of the disclosure are initially described in the context of systems, devices, and circuits with reference to FIGS. 1 and 2. Features of the disclosure are described in the context of manufacturing operations with reference to FIGS. 3A-3H, These and other features of the disclosure are further illustrated by and described in the context of a flowchart that relate to access circuitry structures for 3D memory arrays with reference to FIG. 4.

FIG. 1 illustrates an example of a memory device 100 that supports access circuitry structures for 3D memory arrays in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to memory cell 105 to store, or not store, an electric charge on the charge trapping structure 120 and thereby cause the memory cell 105 store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

In some cases, a memory device 100 may include a 3D memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

The memory device 100 may include a conductive pillar (e.g., a DHC) which may extend through one or more levels of memory cells 105 (e.g., extend through the memory cell stack 175) to couple a bit line 155 with the respective levels of memory cells 105. To access a selected memory cell 105, current may pass from the bit line 155 to the selected memory cell 105 via the conductive pillar (e.g., or from the memory cell 105 to the bit line 155 via the conductive pillar, for example, based on a voltage differential applied across the memory cell 105). In some cases, the amount of current passed to the selected memory cell 105 may decrease as a resistance between the hit line 155 and the conductive pillar increases. In some cases, decreased current passed to the conductive pillar may limit decrease) the quantity of levels of memory cells 105 that may be included in the memory device 100, as there may be insufficient current to support accessing all of the levels of memory cells 105. Thus, lowering the resistance between the bit line 155 and the conductive pillar will increase the quantity of levels of memory cells 105 that may be included in the memory device 100, for example, by increasing the relative amount of current that is passed between the bit line 155 and conductive pillar. As a result, a storage capacity of the memory device 100 may be increased. Additionally or alternatively, decreasing the resistance will reduce power consumption of the memory device 100, for example, supporting a reduced amount of current to be applied to a bit line 155 based on the increased current that is passed between the bit line 155 and conductive pillar.

In accordance with examples described herein, a conductive pillar used to access memory cells 105 and a contact used to couple the conductive pillar with a bit line 155 may be formed such that a contact area between the conductive pillar and the contact may be increased, thereby decreasing a resistance between the conductive pillar and the bit line 155. For example, an increased surface area of the contact and the conductive pillar that are in contact may be associated with a decreased resistance. Forming the conductive pillar such that it protrudes into the contact may increase the surface area of the conductive pillar that is in contact and coupled with the contact, which will reduce the resistance between the conductive pillar and the contact, and thus between the conductive pillar and the bit line

FIG. 2 illustrates an example of a memory architecture 200 that supports access circuitry structures for 3D memory arrays in accordance with examples as disclosed herein. The memory architecture 200 may be an example of a portion of a memory device, such as a memory device 100. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they are the same or would be understood by a person having ordinary skill in the art to be similar. Aspects of the memory architecture 200 may be described with reference to an x-direction, a y-direction, and a z-direction of the illustrated coordinate system.

The memory architecture 200 includes a 3D array of memory cells 205, which may be examples of memory cells 105 described with reference to FIG. 1 (e.g., transistors 110, NAND memory cells). In some examples, the memory cells 205 may be connected in a 31) NAND configuration. For example, the memory cells 205 may be included in a block 210, which may be arranged as a 3D array of in memory cells along the x-direction, n memory cells along the y-direction, and o memory cells along the z-direction. Each memory cell 205 may be located (e.g., addressed) in accordance with an index i along the x-direction, an index j along the y-direction, and an index k along the z-direction (e.g., for locating a memory cell 205-a-ijk). A memory device 100 may include any quantity of one or more blocks 210 in accordance with examples as disclosed herein, and different blocks 210 may be adjacent along the x-direction, along the y-direction, or along the z-direction, or any combination thereof.

In the example of memory architecture 200, the block 210 may be divided into a set of pages 215 (e.g., a quantity of o pages 215) along the z-direction, including a page 215-a-1 associated with memory cells 205-a-111 through 205-a-mn1. In some examples, each page 215 may be associated with a same word line 265, (e.g., a word line 165 described with reference to FIG. 1), which may be coupled with a control gate 115 of each of the memory cells 205 of the page 215, For example, page 215-a-1 may be associated with a word line 265-a-1, and other pages 215-a-i may be associated with a different respective word line 265-a-i (not shown), In some examples, a word line 265 in accordance with the memory architecture 200 may be implemented as planar conductor (e.g., in an xy-plane) that is coupled with each of the memory cells 205 of the page 215.

In the example of memory architecture 200, the block 210 also may be divided into a set of strings 220 (e.g., a quantity of (m×n) strings 220) in an xy-plane, including a string 220-a-mn associated with memory cells 205-a-mn1 through 205-a-mno. In some examples, each string 220 may include a set of memory cells 205 connected in series (e.g., along the z-direction, in Which a drain of one memory cell 205 in the string 220 may be coupled with a source of another memory cell 205 in the string 220). In some examples, memory cells 205 of a string 220 may be implemented along a common channel, such as a pillar channel (e.g., a columnar channel, a pillar of doped semiconductor) along the z-direction. Each memory cell 205 in a string 220 may be associated with a different word line 265, such that a quantity of word lines 265 in the memory architecture 200 may be equal to the quantity of memory cells 205 in a string 220. Accordingly, a string 220 may include memory cells 205 from multiple pages 215, and a page 215 may include memory cells 205 from multiple strings 220.

In some examples, memory cells 205 may be programmed (e.g., set to a logic 0 value) and read from in accordance with a granularity, such as at the granularity of the page 215, but may not be erasable (e.g., reset to a logic 1 value) in accordance with the granularity, such as the granularity of the page 215. For example, NAND memory may instead be erasable in accordance with a different (e.g., higher) level of granularity, such as at the level of granularity the block 210. In some cases, a memory cell 205 may be erased before it may be re-programmed. Different memory devices may have different read, write, or erase characteristics.

In some examples, each string 220 of a block 210 may be coupled with a respective transistor 230 (e.g., a string select transistor, a drain select transistor) at one end of the string 220 (e.g., along the z-direction) and a respective transistor 240 (e.g., a source select transistor, a ground select transistor) at the other end of the string 220. In some examples, a drain of each transistor 230 may be coupled with a bit line 250 of a set of bit lines 250 associated with the block 210, where the bit lines 250 may be examples of bit lines 155 described with reference to FIG. 1. A gate of each transistor 230 may be coupled with a select line 235 (e.g., a string select line, a drain select line). Thus, a transistor 230 may be used to couple a string 220 with a bit line 250 based on applying a voltage to the select line 235, and thus to the gate of the transistor 230. Although illustrated as separate lines along the x-direction, in some examples, select lines 235 may be common to all the transistors 230 associated with the block 210 (e.g., a commonly biased string select node). For example, like the word lines 265 of the block 210, select lines 235 associated with the block 210 may, in some examples, be implemented as a planar conductor (e.g., in an xy-plane) that is coupled with each of the transistors 230 associated with the block 210.

In some examples, a source of each transistor 240 associated with the block 210 may be coupled with a source line 260 of a set of source lines 260 associated with the block 210. In some examples, the set of source lines 260 may be associated with a common source node (e.g., a ground node) corresponding to the block 210. A gate of each transistor 240 may be coupled with a select line 245 (e.g., a source select line, a ground select line). Thus, a transistor 240 may be used to couple a string 220 with a source line 260 based on applying a voltage to the select line 245, and thus to the gate of the transistor 240. Although illustrated as separate lines along the x-direction, in some examples, select lines 245 also may be common to all the transistors 240 associated with the block 210 (e.g., a commonly biased ground select node). For example, like the word lines 265 of the block 210, select lines 245 associated with the block 210 may, in some examples, be implemented as a planar conductor (e.g., in an xy-plane) that is coupled with each of the transistors 240 associated with the block 210.

To operate the memory architecture 200 (e.g., to perform a program operation, a read operation, or an erase operation on one or more memory cells 205 of the block 210), various voltages may be applied to one or more select lines 235 (e.g., to the gate of the transistors 230), to one or more bit lines 250 (e.g., to the drain of one or more transistors 230), to one or more word lines 265, to one or more select lines 245 (e.g., to the gate of the transistors 240), to one or more source lines 260 (e.g., to the source of the transistors 240), or to a bulk for the memory cells 205 (not shown) of the block 210. In some cases, each memory cell 205 of a block 210 may have a common bulk, the voltage of which may be controlled independently of bulks for other blocks 210.

In some cases, as part of a read operation for a memory cell 205, a positive voltage may be applied to the corresponding bit line 250 while the corresponding source line 260 may be grounded or otherwise biased at a voltage lower than the voltage applied to the bit line 250. In some examples, voltages may be concurrently applied to the select line 235 and the select line 245 that are above the threshold voltages of the transistor 230 and the transistor 240, respectively, for the memory cell 205, thereby activating the transistor 230 and transistor 240 such that a channel associated with the string 220 that includes the memory cell 205 (e.g., a pillar channel) may be electrically connected with (e.g., electrically connected between) the corresponding bit line 250 and source line 260. A channel may be an electrical path through the memory cells 205 in the string 220 (e.g., through the sources and drains of the transistors in the memory cells 205 of the string 220) that may conduct current under some operating conditions.

In some examples, multiple word lines 265 (e.g., in some cases all word lines 265) of the block 210—except a word line 265 associated with a page 215 of the memory cell 205 to be read—may concurrently be set to a voltage (e.g., VREAD) that is higher than the threshold voltage (VT) of the memory cells 205. VREAD may cause all memory cells 205 in the unselected pages 215 be activated so that each unselected memory cell 205 in the string 220 may maintain high conductivity within the channel. In some examples, the word line 265 associated with the memory cell 205 to be read may be set to a voltage, VTarget. Where the memory cells 205 are operated as SLC memory cells, VTarget may be a voltage that is between (i) VT of a memory cell 205 in an erased state and (ii) VT of a memory cell 205 in a programmed state.

When the memory cell 205 to be read exhibits an erased VT (e.g., VTarget>VT of the memory cell 205), the memory cell 205 may turn “ON” in response to the application of VTarget to the word line 265 of the selected page 215, which may allow a current to flow in the channel of the string 220, and thus from the bit line 250 to the source line 260. When the memory cell 205 to be read exhibits a programmed T (e.g., VTarget<VT of the selected memory cell), the memory cell 205 may remain “OFF” despite the application of VTarget to the word line 265 of the selected page 215, and thus may prevent a current from flowing in the channel of the string 220, and thus from the bit line 250 to the source line 260.

A signal on the bit line 250 for the memory cell 205 (e.g., an amount of current below or above a threshold) may be sensed (e.g., by a sense component 170 as described with reference to FIG. 1), and may indicate whether the memory cell 205 became conductive or remained non-conductive in response to the application of VTarget to the word line 265 of the selected page 215. The sensed signal thus may be indicative of whether the memory cell 205 was in an erased state (e.g., storing a logic 1) or a programmed state (e.g., storing a logic 0). Though aspects of the example read operation above have been explained in the context of an SLC memory cell 205 for clarity, such techniques may be extended or altered and applied in the context of a multiple-level memory cell 205 (e.g., through the use of multiple values of VTarget corresponding to the different amounts of charge that may be stored in one multiple-level memory cell 205).

In some cases, as part of a program operation for a memory cell 205, charge may be added to a portion of the memory cell 205 such that current flow through the memory cell 205, and thus the corresponding string 220, may be inhibited when the memory cell 205 is later read. For example, charge may be injected into a charge trapping structure 120 as shown in memory cell 105-a of FIG. 1. In some cases, respective voltages may be applied to the word line 265 of the page 215 and the bulk of the memory cell 205 to be programmed such that a control gate 115 of the memory cell 205 is at a higher voltage than the bulk of the memory cell 205 (e.g., a positive voltage may be applied to the word line). Concurrently, voltages may be applied to the select line 235 and the select line 245 that are above the threshold voltages of the transistor 230 and the transistor 240, respectively, thereby activating the transistor 230 and the transistor 240, and the bit line 250 for the memory cell 205 to be programmed may be set to a relatively high voltage. This may cause an electric field such that electrons are pulled from the source of the memory cell 205 towards the drain. The electric field may also cause some of these electrons to be pulled through dielectric material 125 and thereby injected into the charge trapping structure 120 of the memory cell 205, through a process which may in some cases be referred to as tunnel injection.

In some cases, a single program operation may program some or all memory cells 205 in a page 215, as the memory cells 205 of the page 215 may all share a common word line 265 and a common bulk. For a memory cell 205 of the page 215 for which it is not desired to write a logic 0 (e.g., not desired to program the memory cell 205), the corresponding bit line 250 may be set to a relatively low voltage (e.g., ground), which may inhibit the injection of electrons into a charge trapping structure 120. Though aspects of the example program operation above have been explained in the context of an SLC memory cell 205 for clarity, such techniques may be extended and applied to the context of a multiple-level memory cell 205 (e.g., through the use of multiple programming voltages applied to the word line 265, or multiple passes or pulses of a programming voltage applied to the word line 265, corresponding to the different amounts of charge that may be stored in one multiple-level memory cell 205).

In some cases, as part of an erase operation for a memory cell 205, charge may be removed from a portion of the memory cell 205 such that current flow through the memory cell 205, and thus the corresponding string 220, may be uninhibited (e.g., allowed, at least to a greater extent) when the memory cell 205 is later read. For example, charge may be removed from a charge trapping structure 120 as shown in memory cell 105-a of FIG. 1. In some cases, respective voltages may be applied to the word line 265 of the page 215 and the bulk of the memory cell 205 to be erased such that a control gate 115 of the memory cell 205 is at a lower voltage than the bulk of the memory cell 205 (e.g., a positive voltage may be applied to the bulk), which may cause an electric field that pulls electrons out of the charge trapping structure 120 and into the bulk of the memory cell 205. In some cases, a single program operation may erase all memory cells 205 in a block 210, as the memory cells 205 of the block 210 may all share a common bulk.

A memory device that implements the memory architecture 200 (e.g., memory device 100 as described with reference to FIG. 1) may include a conductive pillar (e.g., a conductive line extending in the z-direction between a transistor 230 and a transistor 240) Which may extend through one or more levels of memory cells 205 to couple a bit line 250 with the respective levels of memory cells 205. For example, the conductive pillar may carry current from the bit line 250 to the memory cells 205 of a corresponding string 220 (e.g., at least a portion of a voltage applied to the bit line 250 may be applied to one or more memory cells 205 of the string 220 via the conductive pillar).

In accordance with examples described herein, a conductive pillar for a string 220 and a contact used to couple the conductive pillar with a bit line 250 (e.g., aspects of a transistor 230) may be formed such that a contact area between the conductive pillar and the contact may be increased, thereby decreasing a resistance between the conductive pillar and the bit line 250. For example, forming the conductive pillar such that it protrudes into the contact may increase the surface area of the conductive pillar that is in contact and coupled with the contact, which will reduce the resistance between the conductive pillar and the contact, and thus between the conductive pillar and the bit line As a result, the memory device may support additional levels of memory cells 205 (e.g., additional memory cells 205 may be included in a string 220), thereby supporting scaling of the memory device and increasing a storage capacity of the memory device, among other benefits.

FIG. 3A through 3H illustrate examples of operations that support access circuitry structures for 3D memory arrays in accordance with examples as disclosed herein. For example, FIGS. 3A through 3H may illustrate aspects of a sequence of manufacturing operations for fabricating aspects of a layout 300, which may be a portion of a memory device (e.g., a portion of a memory device 100, a portion of a memory architecture 200). Each view of the FIGS. 3A through 3H may be described with reference to an x-direction, a y-direction, and a z-direction, as illustrated. The manufacturing operations illustrate various cross-sectional views of the layout 300. For example, the manufacturing operations illustrate cross-sectional views of the layout 300 in an xz-plane through the layout 300. Although the layout 300 illustrates examples of certain relative dimensions and quantities of various features, aspects of the layout 300 may be implemented with other relative dimensions or quantities of such features in accordance with examples as disclosed herein.

Operations illustrated in and described with reference to FIGS. 3A through 3H may be performed by a manufacturing system, such as a semiconductor fabrication system configured to perform additive operations such as deposition or bonding, subtractive operations such as etching, trenching, planarizing, or polishing, and supporting operations such as masking, patterning, photolithography, or aligning, among other operations that support the described techniques. In some examples, operations performed by such a manufacturing system may be supported by a process controller or its components as described herein.

FIG. 3A illustrates a portion of a layout 300-a after a first set of one or more manufacturing operations. The first set of manufacturing operations may include forming various structures and materials over a substrate 305. The substrate 305 may be a semiconductor wafer or other substrate over which a stack of layers 310 may be formed (e.g., deposited). The stack of layers 310 may include alternating layers of a first material and a second material. For example, the first material in the stack of layers 310 may be a dielectric material 315 and the second material in the stack of layers 310 may be a sacrificial material 320. In some examples, the sacrificial material 320 may be a nitride material and may be subsequently removed (e.g., etched) and replaced by a conductive material to form, for example, word lines (e.g., word lines 165, word lines 265) or other conductive lines. The quantity of layers depicted in the stack of layers 310 may be for illustrative purposes. For example, the stack of layers 310 may include any quantity of layers of the dielectric material 315 and the sacrificial material 320, including more or less layers than those illustrated.

The first set of manufacturing operations may also include forming a cavity through the stack of layers 310 in the z-direction (e.g., in a direction orthogonal to the substrate 305) and subsequently forming (e.g., depositing) a pillar of materials 325 in the cavity. The pillar of materials 325 may include a conductive pillar 340 (e.g., a pillar formed using a conductive material, such as a metal material), a dielectric material 330-a, a dielectric material 330-b, and an oxide material 345, In some cases, the pillar of materials 325 may also include a nitride material 335. The pillar of materials 325 may be deposited as annuluses in the xy-plane. For example, each material of the pillar of materials may form a cylindrical pillar extending in the z-direction orthogonal to the substrate, where layout 300-a shows a cross-sectional view in the xz-plane of the pillar of materials.

The first set of manufacturing operations may also include planarizing polishing, performing a chemical mechanical planarization (CMP) operation on) the pillar of materials 325. In some cases, the planarizing may be performed such that the dielectric material 330-b, the oxide material 345, and a portion of the stack of layers 310 are planarized to expose the nitride material 335 (e.g., a top surface of the nitride material 335). As a result, a portion of the dielectric material 330-b over the nitride material 335 may be removed and a portion of the dielectric material 330-b between the conductive pillar 340 and the nitride material 335 in the xy-plane may remain. In some cases, the planarizing may be performed such that a portion of the nitride material 335 is removed. For example, the portion of the nitride material 335 may be planarized such that a top surface of the dielectric material 330-a is exposed. A of another portion of the nitride material 335 between the dielectric material 330-a and the dielectric material 330-b in the xy-plane may remain and a top surface of the portion may be exposed. In some cases, the dielectric materials 330 may be referred to as dielectric pillars, with one pillar (e.g., corresponding to the dielectric material 330-a) being between the nitride material 335 and the stack of layers 310 in the xy-plane and another pillar (e.g., corresponding to the dielectric material 330-b) being between the conductive pillar 340 and the nitride material 335 in the xy-plane.

Although the structures and materials are illustrated as being deposited in direct contact with the substrate 305, in some other examples, the layout 300-a may include other materials or components between the structures and materials and the substrate 305, such as interconnection or routing circuitry (e.g., access lines), control circuitry (e.g., transistors, aspects of a local memory controller, decoders, multiplexers), or other structures and materials (e.g., other structures and materials that have been processed in accordance with examples as disclosed herein), which may include various conductor, semiconductor, or dielectric materials between the structures and materials and the substrate 305. For example, the layout 300-a may include a layer including thin-film-transistors (TFTs) between the substrate 305 and the structures and materials, and/or access lines and transistors (e.g., a source line 260, a select line 245, a transistor 240) between the substrate 305 and the structures and materials, among others. In some examples, the substrate 305 itself may include such interconnection or routing circuitry.

FIG. 3B illustrates a portion of a layout 300-b after a second set of one or more manufacturing operations. The second set of manufacturing operations may include a recess operation (e.g., etch operation). The recess operation may include removing (e.g., etching) a portion of the nitride material 335 to form recesses (e.g., cavities) in the pillar of materials 325. For example, the annulus of the nitride material 335 (e.g., the pillar of nitride material 335) may be etched such that a cavity 347 is formed between the dielectric material 330-a and the dielectric material 330-b. After performing the recess operations, the top surface of the nitride material 335 may be below, in the z-direction, the top surfaces of the dielectric material 330, the conductive pillar 340, the oxide material 345, and a top layer of the dielectric material 315 of the stack of layers 310. Additionally, in some cases, a top surface of the dielectric material 330-b may be exposed as a result of the recess operation.

In some cases, the recess operation may include a wet etch (e.g., a solution phase etch) to etch the nitride material 335. In some cases, the recess operation may include a vapor etch. For example, in some cases the wet etch may affect (e.g., etch) one or more portions (e.g., a seam) of the oxide material 345 such that a structural integrity of the pillar of materials 325 is reduced or such that there may be variations between multiple pillars of materials 325 of the memory device. The vapor etch, however, may not affect the oxide material 345. In some cases, the wet etch may be more cost effective (e.g., cost less) than the vapor etch and therefore may reduce a cost of manufacturing the memory device.

FIG. 3C illustrates a portion of a layout 300-c after a third set of one or more manufacturing operations. The third set of manufacturing operations may include etching the dielectric materials 330, the oxide material 345, and a portion of the stack of layers 310 (e.g., a portion of a dielectric material 315-a corresponding to the top layer of dielectric material 315 of the stack of layers 310). For example, the etching may form a cavity 348 in a portion of the dielectric material 315-a and the dielectric materials 330 (e.g., between the conductive pillar 340 and a remaining portion of the dielectric material 315-a) and a cavity 349 in the oxide material 345 (e.g., inside of the conductive pillar 340 in the xy-plane). The conductive pillar 340 may be un-etched and may protrude from the pillar of materials 325 (e.g., the dielectric material 330, the oxide material 345, and the nitride material 335) in the z-direction (e.g., orthogonal to the substrate 305). For example, based on the etching, one or more sidewalls of the conductive pillar 340 may be exposed based on the cavity 348 and the cavity 349 surrounding the one or more sidewalls of the conductive pillar 340. In some cases, the dielectric materials 330 and the oxide material 345 may be etched to the top surface of the nitride material 335 based on the recess operation shown in FIG. 3B. In some cases, the dielectric materials 330 and the oxide material 345 may be etched to the top surface of the nitride material 335 (e.g., in the z-direction, orthogonal to the substrate 305) such that the top surfaces of the dielectric materials 330, the oxide material 345, and the nitride material 335 are level (e.g., in the xy-plane). In some cases, the etch may be a vapor etch. For example, a vapor etch may etch the dielectric material 330, the oxide material 345, and the dielectric material 315-a at a same rate, whereas other types of etching operations (e.g., wet etches) may etch different materials at different rates based on varying material densities.

FIG. 3D illustrates a portion of a layout 300-d after a fourth set of one or more manufacturing operations. The fourth set of manufacturing operations may include depositing a first conductive material 350 (e.g., a polysilicon material) over the pillar of materials 325 such that the first conductive material 350 is in contact with the conductive pillar 340 protruding from the pillar of materials 325. For example, the first conductive material 350 may be in contact with one or more sidewalls (e.g., the exposed sidewalls) of a protruding portion of the conductive pillar 340, which may extend through the first conductive material 350 in the z-direction (e.g., orthogonal to the substrate 305). In some cases, the first conductive material may be deposited such that it is also over the dielectric material 315-a and the conductive pillar 340, for example, such that the first conductive material is in contact with a top surface of the dielectric material 315-a, a top surface of the conductive pillar 340, or a combination thereof.

The fourth set of manufacturing operations may also include planarizing the first conductive material 350 and the conductive pillar 340. For example, the first conductive material 350 and the conductive pillar 340 may be planarized such that a top surface of the conductive material 350 and the top surface of the conductive pillar 340 may be level with a top surface of the dielectric material 315-a (e.g., a top surface of an unetched portion of the stack of layers 310) in the z-direction. In some examples, planarizing the first conductive material 350 and the conductive pillar 340 may expose the top surface of the conductive pillar 340, the top surface of the dielectric material 315-a, or a combination thereof.

FIG. 3E illustrates a portion of a layout 300-e after a fifth set of one or more manufacturing operations. The fifth set of manufacturing operations may include forming (e.g., depositing) a stack of layers 312 over the stack of layers 310, the conductive material 350, and the conductive pillar 340. In some cases, forming the stack of layers 312 may be based on the planarizing described with reference to FIG. 3D. For example, the stack of layers 312 may be formed after the planarizing. Additionally or alternatively, the planarizing may increase a uniformity of thickness (e.g., height) in the z-direction across the xy-plane of the stack of layers 312, for example, by providing a level surface over which the stack of layers 312 may be formed. The stack of layers 312 may include alternating layers of a first material and a second material, as described with reference to FIG. 3A. For example, the first material in the stack of layers 312 may be the dielectric material 315 and the second material in the stack of layers 312 may be the sacrificial material 320. In some examples, the sacrificial material 320 may be a nitride material and may be subsequently removed (e.g., etched) and replaced by a conductive material to form, for example, conductive lines or word lines. The quantity of layers depicted in the stack of layers 312 may be for illustrative purposes. For example, the stack of layers 312 may include any quantity of layers of the dielectric material 315 and the sacrificial material 320, including more or less layers than those illustrated.

The fifth set of manufacturing operations may also include forming (e.g., etching) a cavity 360 through the stack of layers 312 and to at least a portion of the first conductive material 350. In some cases, the cavity 360 may also be formed to a portion of the conductive pillar 340. For example, the cavity 360 may extend to the first conductive material 350, the conductive pillar 340, or both. In some cases, the first conductive material 350, the conductive pillar 340, or both, may be (e.g., function as) an etch stop for an etching operation used to form the cavity 360. For example, the cavity 360 may end at the top surfaces of the first conductive material 350 and the conductive pillar 340. In some cases, a relatively small portion of the first conductive material 350, the conductive pillar 340, or both, may be etched as part of the formation of the cavity 360, but the first conductive material 350, the conductive pillar 340, or both, may otherwise function as the etch stop.

In some cases, forming the cavity 360 may allow for a contact to be formed between the conductive pillar 340 and a bit line that conserves space of the memory device by allowing for pillars of the memory device (e.g., each including the conductive pillar 340 and the pillar of materials 325) to be arranged more closely together (e.g., have smaller pillar pitches in the x-direction, the y-direction, or both). For example, each bit line may be coupled with a unique column of conductive pillars 340, such that the column is uniquely addressable by a respective bit line. If a bit line were directly coupled with conductive pillars, an unintentional overlap of the bit line with a conductive pillar of another column (e.g., due to the close proximity of conductive pillars) may result in unintentional coupling with a conductive pillar of the other column, which may result in errors while accessing memory cells associated with one or more of the columns. However, forming the cavity 360 and a contact in cavity 360, thereby physically separating the conductive pillars and the bit lines, may allow the conductive pillars of the memory device to be closely arranged without unintentional coupling.

The fifth set of manufacturing operations may also include depositing a dielectric material 355 over the stack of layers 312 and in the cavity 360. For example, the dielectric material may be deposited over a top layer of dielectric material 315 of the stack of layers 312, on sidewalk of the cavity 360, on a bottom of the cavity 360 (e.g., over the exposed first conductive material 350, the conductive pillar 340, or both), or a combination thereof. In some examples, the fifth set of manufacturing operations may include etching a portion of the dielectric material 355 at a bottom of the cavity 360, for example, to expose a portion of the first conductive material 350, the conductive pillar 340, or both.

FIG. 3F illustrates a portion of a layout 300-f after a sixth se of one or more manufacturing operations. The sixth set of manufacturing operations may include etching a portion of the first conductive material 350, a portion of the conductive pillar 340, or both to expand the cavity 360 into the first conductive material 350, the conductive pillar 340, or both. For example, expanding the cavity 360 may include etching a cavity 365 in the first conductive material 350, the conductive pillar 340, or both. Expanding the cavity 360 to include an expanded cavity 365 may increase an exposed surface area of the first conductive material 350, the conductive pillar 340, or both, relative to respective surface areas exposed as a result of the formation of the cavity 360. For example, based on the expansion of the cavity 360, a portion of the first conductive material 350 and, in some cases, a portion the conductive pillar 340, may be removed resulting in an increased surface area of the first conductive material 350 and/or the conductive pillar 340 that are exposed. In some cases, the etch to form the expanded cavity 365 may be a wet etch (e.g., a solution phase etchant, such as tetramethyl ammonium hydroxide (TMAH) or ammonium hydroxide, among other wet etchants). In some cases, the etch to form the expanded cavity 365 may be a vapor etch.

FIG. 3G illustrates a portion of a layout 300-g after a seventh set of one or more manufacturing operations. The seventh set of manufacturing operations may include depositing a second conductive material 370 polysilicon) in the cavity 360 (e.g., including the expanded cavity 365). The first conductive material 350 and the second conductive material 370 may together form a contact which may be used to couple the conductive pillar 340 with a bit line. The second conductive material 370 may be in contact with the first conductive material 350, the conductive pillar 340, or both. In some cases, the second conductive material 370 may be directly coupled with the conductive pillar 340, for example, if the second conductive material 370 is in contact with the conductive pillar 340. Here, the second conductive material 370 may further be coupled with the conductive pillar 340 via the first conductive material 350.

In other cases, the second conductive material 370 may be indirectly coupled with the conductive pillar 340 via the first conductive material 350. For example, the second conductive material 370 may be separated from the conductive pillar 340 by the first conductive material 350, The first conductive material 350 may separate the second conductive material 370 and the conductive pillar 340 based on the location of the cavity 360 in relation to the first conductive material 350 and the conductive pillar 340. For example, the cavity 360 may be etched (e.g., and expanded) such that a surface of the conductive pillar 340 is unexposed (e.g., still covered by the first conductive material 350). Here, the second conductive material 370 and the conductive pillar 340 may be physically separated by the first conductive material 350, but may be electrically coupled based on the first conductive material 350 being conductive.

When the cavity 360 is expanded to include the expanded cavity 365, the second conductive material 370 may also be deposited in the expanded cavity 365, which may increase the surface area of the deposited second conductive material 370. For example, based on removing a portion of the first conductive material 350, and in some cases, a portion of the conductive pillar 340 an increased volume of the second conductive material 370 may be deposited, which may correspond to an increased surface are of the deposited second conductive material 370 in contact with the first conductive material 350. The increased surface area of the deposited second conductive material 370 in contact with the first conductive material 350, the conductive pillar 340, or both, may correspond to an increased contact area between the second conductive material 370 and the conductive pillar 340 (e.g., via direct contact or via the first conductive material 350), for example, relative to if the cavity 360 were not expanded. As a result, a resistance between the conductive pillar 340 and the contact (e.g., the second conductive material 370) may decrease.

FIG. 3H illustrates a portion of a layout 300-h after an eighth set of one or more manufacturing operations. The eighth set of manufacturing operations may include removing the layers of the sacrificial material 320, as described with reference to FIGS. 3A and 3E, in the stack of layers 310 and the stack of layers 312. Word lines 375 may be formed at respective locations of the sacrificial material 320 in the stack of layers 310, and conductive lines 380 may be formed at respective locations of the sacrificial material 320 in the stack of layers 312. The word lines 375 may be associated with accessing memory cells 385 and the conductive lines 380 may be associated with activating the second conductive material 370 to couple a bit line 395 with the conductive pillar 340. The nitride material 335, as described with reference to FIGS. 3A through 3D, may also be removed. A set of levels of memory cells 385 may be formed over the substrate 305 at intersections between respective word lines 375 and the conductive pillar 340 based on removing the nitride material 335. A dielectric material 317 may be formed at a location of the removed nitride 335 where memory cells 385 are not formed. A dielectric material 318 may be deposited to fill a remaining portion of the cavity 360 (e.g., and the expanded cavity 365) unfilled by the second conductive material 370.

The memory cells 385 may be coupled with the conductive pillar 340, which may extend through the set of levels of memory cells 385 such that there may be one or more respective memory cells 385 coupled with the conductive pillar 340 at each level. A dielectric pillar 330-b may also extend through the set of levels of memory cells 385 and may be located between the conductive pillar 340 and the memory cells 385, while a dielectric pillar 330-a may extend through the set of levels of memory cells 385 and may be located between the memory cells 385 and the word lines 375. Based on the manufacturing operations described with reference to EEGs. 3A through 3C, the conductive pillar 340 may protrude above a top surface of the dielectric pillars 330 in the z-direction (e.g., orthogonal to the substrate 305).

The eighth set of manufacturing operations may include planarizing a top surface in the z-direction of the layout 300-h. For example, the top surface of the layout 300-h may be planarized such that a top surface of the stack of layers 312 (e.g., a top surface of the dielectric material 315) is exposed. The planarizing may include planarizing portions of the second conductive material 370 and the dielectric material 355 over the stack of layers 312 in the xy-plane (e.g., as shown in FIG. 3G) such that the portions of the conductive material 370 and a portion of the dielectric material 355 are removed and the top surface of the stack of layers 312 is exposed. The bit line 395 may be formed over the stack of layers 312 (e.g., after the planarizing), the set of levels of memory cells 385, the conductive pillar 340, and the contact (e.g., including the first conductive material 350 and the second conductive material 370). The bit line 395 may be associated with accessing the memory cells 385 coupled with the conductive pillar 340. The contact including the first conductive material 350 and the second conductive material 370 may be located between the bit line 395 and the pillar of materials 325. The contact may be coupled with the conductive pillar 340 and may be configured to couple the bit line 395 with the conductive pillar 340. For example, the bit line 395 may be coupled with the conductive pillar 340 via the first conductive material 350 and the second conductive material 370, which may extend from the bit line 395 (e.g., a contact layer 390 coupled with the bit line 395) to the first conductive material 350, the conductive pillar 340, or both.

The conductive pillar 340 may protrude above the top surface of the dielectric pillars 330 and may extend into the contact (e.g., into or through the first conductive material 350) in the z-direction. The first conductive material 350 may be in contact with one or more sidewalls of the conductive pillar 340, which may increase the contact area between the conductive pillar 340 and the contact. In some cases, the contact may include the second conductive material 370 located at least partially in a cavity in the first conductive material 350, the conductive pillar 340, or both (e.g., the cavity 360 as described with reference to FIGS. 3F and 3G). The first conductive material 350 may be a first polysilicon material and the second conductive material 370 may be a second polysilicon material. In some cases, the first polysilicon material and the second polysilicon material may be different, while in other cases they may be the same. Forming the bit line 395 may also include forming a contact layer 390 between the bit line 395 and the second conductive material 370.

The contact between the bit line 395 and the conductive pillar 340 (e.g., the first conductive material 350 and the second conductive material 370) may be used to access a memory cell 385. For example, the memory cell 385 may be accessed when the bit line 395 is activated (e.g., a voltage is applied to the bit line 395) and current passes from the bit line 395 to the conductive pillar 340 via the contact, and when the respective word line 375 is activated, thereby resulting in a voltage differential across the memory cell 385, The conductive pillar protruding into the contact and the contact area between the first conductive material 350 and the second conductive material 370 may increase the contact area between the conductive pillar 340 and the contact, thereby reducing a resistance between the contact and the conductive pillar 340. The increased contact area may reduce a resistance between the conductive pillar 340 and the bit line 295, which may reduce power consumption, improve current transfer between the conductive pillar 340 and the bit line 395, and support scaling of the memory device to include more levels of memory cells 385.

FIG. 4 shows a flowchart illustrating a method 400 that supports access circuitry structures for 3D memory arrays in accordance with examples as disclosed herein. The operations of method 400 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 405, the method may include forming a pillar of materials in a first cavity through a first stack of layers over a substrate, the pillar of materials including a conductive pillar, a first dielectric material, and a first oxide material. The operations of 405 may be performed in accordance with examples as disclosed herein.

At 410, the method may include etching the first dielectric material, the first oxide material, and a portion of the first stack of layers, the conductive pillar protruding from the pillar of materials in a first direction orthogonal to the substrate based at least in part on the etching. The operations of 410 may be performed in accordance with examples as disclosed herein.

At 415, the method may include depositing a first conductive material over the pillar of materials, the first conductive material in contact with the conductive pillar protruding from the pillar of materials. The operations of 415 may be performed in accordance with examples as disclosed herein.

At 420, the method may include forming a second stack of layers over the first stack of layers, the first conductive material, and the pillar of materials. The operations of 420 may be performed in accordance with examples as disclosed herein.

At 425, the method may include forming a second cavity through the second stack of layers and to a portion of the first conductive material. The operations of 425 may be performed in accordance with examples as disclosed herein.

At 430, the method may include depositing a second conductive material in the second cavity. The operations of 430 may be performed in accordance with examples as disclosed herein.

At 435, the method may include forming a bit line over the second stack of layers, where the bit line is coupled with the conductive pillar via the first conductive material and the second conductive material. The operations of 435 may be performed in accordance with examples as disclosed herein.

In some examples, an apparatus (e.g., a manufacturing system) as described herein may perform a method or methods, such as the method 400. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:
Aspect 1: A method or apparatus further including operations, features, circuitry, logic, means, or instructions, or any combination thereof for forming a pillar of materials in a first cavity through a first stack of layers over a substrate, the pillar of materials including a conductive pillar, a first dielectric material, and a first oxide material; etching the first dielectric material, the first oxide material, and a portion of the first stack of lavers, the conductive pillar protruding from the pillar of materials in a first direction orthogonal to the substrate based at least in part on the etching; depositing a first conductive material over the pillar of materials, the first conductive material in contact with the conductive pillar protruding from the pillar of materials; forming a second stack of layers over the first stack of layers, the first conductive material, and the pillar of materials; forming a second cavity through the second stack of layers and to a portion of the first conductive material; depositing a second conductive material in the second cavity; and forming a bit line over the second stack of layers, where the bit line is coupled with the conductive pillar via the first conductive material and the second conductive material.
Aspect 2: The method or apparatus of aspect 1, where the pillar of materials includes a nitride material, and the method or apparatus of aspect 1 further include operations, features, circuitry, logic, means, or instructions, or any combination thereof for etching, before etching the first dielectric material, the first oxide material, and the portion of the first stack of layers, the nitride material, where etching the first dielectric material, the first oxide material, and the portion of the first stack of layers is based at least in part on etching the nitride material.
Aspect 3: The method or apparatus of aspect 2, further including operations, features, circuitry, logic, means, or instructions, or any combination thereof for planarizing the first dielectric material, the first oxide material, and the portion of the first stack of layers to expose the nitride material, where etching the nitride material is based at least in part on exposing the nitride material.
Aspect 4: The method or apparatus of any of aspects 2 through 3, where the first dielectric material, the first oxide material, and the portion of the first stack of layers are etched to a top surface of the etched nitride material in the first direction orthogonal to the substrate.
Aspect 5: The method or apparatus of any of aspects 1 through 4, further including operations, features, circuitry, logic, means, or instructions, or any combination thereof for planarizing the first conductive material and the conductive pillar, where forming the second stack of layers over the first stack of layers is based at least in part on the planarizing.
Aspect 6: The method or apparatus of aspect 5, where a top surface of the first conductive material and a top surface of the conductive pillar are level with a top surface of an unetched portion of the first stack of layers based at least in part on the planarizing.
Aspect 7: The method or apparatus of any of aspects 1 through 6, further including operations, features, circuitry, logic, means, or instructions, or any combination thereof for etching, before depositing the second conductive material, the portion of the first conductive material, a portion of the conductive pillar, or both, to expand the second cavil into the first conductive material, the conductive pillar, or both, where the second conductive material is in contact with the first conductive material, the conductive pillar, or both, based at least in part on the expansion of the second cavity
Aspect 8: The method or apparatus of any of aspects 1 through 7, where the second cavity extends into the first conductive material, the conductive pillar, or both and the second conductive material is in contact with the first conductive material, the conductive pillar, or both.
Aspect 9: The method or apparatus of any of aspects 1 through 8, where the first conductive material is in contact with one or more sidewalls of a portion of the conductive pillar that protrudes from the pillar of materials.
Aspect 10: The method or apparatus of any of aspects 1 through 9, where a portion of the conductive pillar that protrudes from the pillar of materials extends through the first conductive material.
Aspect 11: The method or apparatus of any of aspects 1 through 10, where the first stack of layers and the second stack of layers include alternating layers of a first material and a second dielectric material.
Aspect 12: The method or apparatus of aspect 11, further including operations, features, circuitry, logic, means, or instructions, or any combination thereof for removing the layers of first material in the first stack of layers and the second stack of layers based at least in part on the first material being a sacrificial material; forming word lines at respective locations of the removed layers of the first material in the first stack of layers; forming conductive lines at respective locations of the removed layers of the first material in the second stack of layers, the conductive lines for activating the second conductive material to couple the bit line with the conductive pillar; and forming respective memory cells between respective word lines and the conductive pillar.
Aspect 13: The method or apparatus of any of aspects 1 through 12, further including operations, features, circuitry, logic, means, or instructions, or any combination thereof for depositing, before depositing the second conductive material in the second cavity, a second dielectric material in the second cavity and etching a portion of the second dielectric material to expose the portion of the first conductive material.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 14: An apparatus, including: a substrate; a plurality of levels of memory cells over the substrate; a plurality of word lines associated with accessing the plurality of levels of memory cells; a conductive pillar extending through the plurality of levels of memory cells and coupled with one or more respective memory cells at each level of the plurality of levels of memory cells; a dielectric pillar extending through the plurality of levels of memory cells and located between the conductive pillar and the one or more respective memory cells, where the conductive pillar protrudes above a top surface of the dielectric pillar in a first direction orthogonal to the substrate; a bit line associated with accessing the plurality of levels of memory cells; and a contact coupled with the conductive pillar based at least in part on the conductive pillar protruding above the top surface of the dielectric pillar and configured to couple the bit line with the conductive pillar,
Aspect 15: The apparatus of aspect 14, where the conductive pillar extends into the contact in the first direction based at least in part on protruding above the top surface of the dielectric pillar and is coupled with the contact based at least in part on extending into the contact.
Aspect 16: The apparatus of aspect 15, where the contact includes a first conductive material and a second conductive material, the conductive pillar extending into the first conductive material in the first direction.
Aspect 17: The apparatus of aspect 16, further including: a cavity in the first conductive material, the conductive pillar, or both, where the second conductive material is at least partially located in the cavity.
Aspect 18: The apparatus of any of aspects 16 through 17, where the first conductive material is a first polysilicon material and the second conductive material is a second polysilicon material.
Aspect 19: The apparatus of any of aspects 14 through 18, where the contact is in contact with one or more sidewalk of the conductive pillar.

An apparatus is described. The following provides an overview of aspects of the apparatus as described herein:
Aspect 20: An apparatus, including: a conductive pillar extending through a plurality of levels of memory cells coupled with one or more memory cells at each level of the plurality of levels of memory cells; a bit line configured to access the one or more memory cells via the conductive pillar; and a contact configured to couple the conductive pillar with the bit line, the contact including: a first conductive material in contact with one or more sidewalls of the conductive pillar based at least in part on the conductive pillar extending through the first conductive material; and a second conductive material extending from the bit line at least to the first conductive material.
Aspect 21: The apparatus of aspect 20, further including: a cavity in the first conductive material, the conductive pillar; or both, where the second conductive material is at least partially located in the cavity.
Aspect 22: The apparatus of any of aspects 20 through 21, where the second conductive material is in contact with the first conductive material and the conductive pillar.
Aspect 23: The apparatus of any of aspects 20 through 22, where: the second conductive material is contact with the first conductive material and physically separated from the conductive pillar by the first conductive material, and the second conductive material is coupled with the conductive pillar via the first conductive material.
Aspect 24: The apparatus of any of aspects 20 through 23, where: the bit line is located over the plurality of levels of memory cells, the conductive pillar, and the contact, and the contact is located between the bit line and the plurality of levels of memory cells.
Aspect 25: The apparatus of any of aspects 20 through 24, where the first conductive material is a first polysilicon material and the second conductive material is a second polysilicon material.

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” refers to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The terms “if,” “when,” “based on,” or “based at least in part on” may be used interchangeably. In some examples, if the terms “if,” “when.” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the EFT may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type EFT, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with e appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, described functions can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or one or more or) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
forming a pillar of materials in a first cavity through a first stack of layers over a substrate, the pillar of materials comprising a conductive pillar, a first dielectric material, and a first oxide material;
etching the first dielectric material, the first oxide material, and a portion of the first stack of layers, the conductive pillar protruding from the pillar of materials in a first direction orthogonal to the substrate based at least in part on the etching;
depositing a first conductive material over the pillar of materials, the first conductive material in contact with the conductive pillar protruding from the pillar of materials;
forming a second stack of layers over the first stack of layers, the first conductive material, and the pillar of materials;
forming a second cavity through the second stack of layers and to a portion of the first conductive material;
depositing a second conductive material in the second cavity; and
forming a bit line over the second stack of layers, wherein the bit line is coupled with the conductive pillar via the first conductive material and the second conductive material.

2. The method of claim 1, wherein the pillar of materials comprises a nitride material, the method further comprising:
etching, before etching the first dielectric material, the first oxide material, and the portion of the first stack of layers, the nitride material, wherein etching the first dielectric material, the first oxide material, and the portion of the first stack of layers is based at least in part on etching the nitride material.

3. The method of claim 2, further comprising:
planarizing the first dielectric material, the first oxide material, and the portion of the first stack of layers to expose the nitride material, wherein etching the nitride material is based at least in part on exposing the nitride material.

4. The method of claim 2, wherein the first dielectric material, the first oxide material, and the portion of the first stack of layers are etched to a top surface of the etched nitride material in the first direction orthogonal to the substrate.

5. The method of claim 1, further comprising:
planarizing the first conductive material and the conductive pillar, wherein forming the second stack of layers over the first stack of layers is based at least in part on the planarizing.

6. The method of claim 5, wherein a top surface of the first conductive material and a top surface of the conductive pillar are level with a top surface of an unetched portion of the first stack of layers based at least in part on the planarizing.

7. The method of claim 1, further comprising:
etching, before depositing the second conductive material, the portion of the first conductive material, a portion of the conductive pillar, or both, to expand the second cavity into the first conductive material, the conductive pillar, or both, wherein the second conductive material is in contact with the first conductive material, the conductive pillar, or both, based at least in part on the expansion of the second cavity.

8. The method of claim 1, wherein:
the second cavity extends into the first conductive material, the conductive pillar, or bath, and
the second conductive material is in contact with the first conductive material, the conductive pillar, or both.

9. The method of claim 1, wherein the first conductive material is in contact with one or more sidewalls of a portion of the conductive pillar that protrudes from the pillar of materials.

10. The method of claim 1, wherein a portion of the conductive pillar that protrudes from the pillar of materials extends through the first conductive material.

11. The method of claim 1, wherein the first stack of layers and the second stack of layers comprise alternating layers of a first material and a second dielectric material.

12. The method of claim 11, further comprising:
removing the layers of first material in the first stack of layers and the second stack of layers based at least in part on the first material being a sacrificial material;
forming word lines at respective locations of the removed layers of the first material in the first stack of layers;
forming conductive lines at respective locations of the removed layers of the first material in the second stack of layers, the conductive lines for activating the second conductive material to couple the bit line with the conductive pillar; and
forming respective memory cells between respective word lines and the conductive pillar.

13. The method of claim 1, further comprising:
depositing, before depositing the second conductive material in the second cavity, a second dielectric material in the second cavity; and
etching a portion of the second dielectric material to expose the portion of the first conductive material.

14. An apparatus, comprising:
a substrate;
a plurality of levels of memory cells over the substrate;
a plurality of word lines associated with accessing the plurality of levels of memory cells;
a conductive pillar extending through the plurality of levels of memory cells and coupled with one or more respective memory cells at each level of the plurality of levels of memory cells;
a dielectric pillar extending through the plurality of levels of memory cells and located between the conductive pillar and the one or more respective memory cells, wherein the conductive pillar protrudes above a top surface of the dielectric pillar in a first direction orthogonal to the substrate;
a bit line associated with accessing the plurality of levels of memory cells; and
a contact coupled with the conductive pillar based at least in part on the conductive pillar protruding above the top surface of the dielectric pillar and configured to couple the bit line with the conductive pillar.

15. The apparatus of claim 14, wherein the conductive pillar extends into the contact in the first direction based at least in part on protruding above the top surface of the dielectric pillar and is coupled with the contact based at least in part on extending into the contact.

16. The apparatus of claim 15, wherein the contact comprises a first conductive material and a second conductive material, the conductive pillar extending into the first conductive material in the first direction.

17. The apparatus of claim 16, further comprising:
a cavity in the first conductive material, the conductive pillar, or both, wherein the second conductive material is at least partially located in the cavity.

18. The apparatus of claim 16, wherein the first conductive material is a first polysilicon material and the second conductive material is a second polysilicon material.

19. The apparatus of claim 14, wherein the contact is in contact with one or more sidewalls of the conductive pillar.

20. An apparatus, comprising:
a conductive pillar extending through a plurality of levels of memory cells coupled with one or more memory cells at each level of the plurality of levels of memory cells;
a bit line configured to access the one or more memory cells via the conductive pillar; and
a contact configured to couple the conductive pillar with the bit line, the contact comprising:
a first conductive material in contact with one or more sidewalls of the conductive pillar based at least in part on the conductive pillar extending through the first conductive material; and
a second conductive material extending from the bit line at least to the first conductive material.

21. The apparatus of claim 20, further comprising:
a cavity in the first conductive material, the conductive pillar, or both, wherein the second conductive material is at least partially located in the cavity.

22. The apparatus of claim 20, wherein the second conductive material is in contact with the first conductive material and the conductive pillar.

23. The apparatus of claim 20, wherein:
the second conductive material is contact with the first conductive material and physically separated from the conductive pillar by the first conductive material, and
the second conductive material is coupled with the conductive pillar via, the first conductive material.

24. The apparatus of claim 20, wherein:
the bit line is located over the plurality of levels of memory cells, the conductive pillar, and the contact, and
the contact is located between the bit line and the plurality of levels of memory cells.

25. The apparatus of claim 20, wherein the first conductive material is a first polysilicon material and the second conductive material is a second polysilicon material.
